(19) United States
(12) Patent Application Publication
(10) Pub. No.: US 2015/0318503 A1
(43) Pub. Date: Nov. 5, 2015

(54) FIELD EFFECT TRANSISTOR AND MANUFACTURING METHOD THEREOF

(71) Applicant: Semiconductor Manufacturing International (Shanghai) Corporation, Shanghai (CN)

(72) Inventor: Deyuan XIAO, Shanghai (CN)

(21) Appl. No.: 14/559,368

(22) Filed: Dec. 3, 2014

(30) Foreign Application Priority Data
May 5, 2014 (CN) 201410185027.2

(51) Int. Cl. H01L 51/05; H01L 51/10; H01L 51/00

(52) U.S. Cl. CPC H01L 51/0558; H01L 51/0002; H01L 51/105; H01L 51/0018; H01L 51/0021; H01L 51/102; H01L 51/0516; H01L 51/055; H01L 51/0048

(57) ABSTRACT

A field effect transistor is disclosed. The field effect transistor includes a substrate, a carbon nanotube formed above the substrate, a gate electrode formed on the substrate, wherein the gate electrode is formed surrounding a center portion of the carbon nanotube, and a source electrode and a drain electrode formed on the substrate, wherein the source electrode and the drain electrode are formed surrounding respective end portions of the carbon nanotube.

### CROSS-REFERENCE TO RELATED APPLICATION

This application claims priority to Chinese Patent Application No. 201410185027.2 filed on May 5, 2014, the disclosure of which is incorporated herein by reference in its entirety.

### BACKGROUND

1. Technical Field

The present disclosure relates to a semiconductor device and manufacturing method thereof. More particularly, it discloses a method of manufacturing a field effect transistor.

2. Description of the Related Art

According to Moore's Law, VLSI (Very Large Scale Integration) circuit performance is improved and device cost is reduced as feature sizes in traditional MOSFETs (Metal Oxide Semiconductor Field Effect Transistors) continue to decrease. However, when device dimensions are reduced to sub-micron or nanometer scale (for example, below the 22 nm node), challenges in semiconductor device fabrication and performance arise. These challenges include electron tunneling through the short channel and thin insulating film, which may cause current leakage, short channel effects, passive power consumption, as well as changes in the device structure and doping profile.

Some of the above challenges may be overcome by replacing the conventional MOSFET with carbon nanotube field effect transistors (CNTFETs). The use of CNTFETs can also help to further reduce device dimensions.

The prior art discloses a carbon nanotube field effect transistor having a planar structure. In the planar-type CNTFET, a gate is formed on a substrate and a carbon nanotube is formed above the gate. A source region and a drain region are formed on the substrate on the respective ends of the carbon nanotube.

The prior art also discloses a carbon nanotube field effect transistor having a wrap-around structure. In the wrap-around type CNTFET, a trench is formed on the substrate and a carbon nanotube is formed on the trench. A gate is formed surrounding the carbon nanotube in the trench. A source region and a drain region are formed on the substrate on the respective ends of the carbon nanotube.

However, in both the above prior art CNTFETs, the gate control of the carbon nanotube is generally weaker, and the electron barrier between the source region and the drain region is generally greater, which could affect the device performance of the field effect transistor.

### SUMMARY

The present disclosure addresses at least the above deficiencies in the prior art CNTFETs.

According to one embodiment of the inventive concept, a field effect transistor is provided. The field effect transistor includes: a substrate; a carbon nanotube formed above the substrate; a gate electrode formed on the substrate, wherein the gate electrode is formed surrounding a center portion of the carbon nanotube; and a source electrode and a drain electrode formed on the substrate, wherein the source electrode and the drain electrode are formed surrounding respective end portions of the carbon nanotube.

In one embodiment, the field effect transistor may further include a high-K dielectric layer formed between the carbon nanotube and the gate electrode surrounding the center portion of the carbon nanotube.

In one embodiment, the field effect transistor may further include a spacer formed on both side portions of the gate electrode.

In one embodiment, the carbon nanotube may be formed by reacting a metal catalyst with a carbon-based compound.

In one embodiment, the carbon-based compound may include at least one of methane, ethylene, acetylene, carbon monoxide, and benzene.

In one embodiment, the metal catalyst may include at least one of platinum, gold, silver, copper, and nickel.

In one embodiment, the carbon nanotube may be a single-walled carbon nanotube.

According to another embodiment of the inventive concept, a method of manufacturing a field effect transistor is provided. The method includes: forming a carbon nanotube above a substrate; forming a gate electrode on the substrate, wherein the gate electrode is formed surrounding a center portion of the carbon nanotube; and forming a source electrode and a drain electrode on the substrate, wherein the source electrode and the drain electrode are formed surrounding respective end portions of the carbon nanotube.

In one embodiment, forming the carbon nanotube above the substrate may further include: forming a porous silicon layer on the substrate; introducing a metal catalyst onto a surface of the porous silicon layer in a region where the carbon nanotube is to be formed; and reacting the metal catalyst with a carbon-based compound so as to form the carbon nanotube in the region on the surface of the porous silicon layer.

In one embodiment, the carbon-based compound may include at least one of methane, ethylene, acetylene, carbon monoxide, and benzene.

In one embodiment, forming the gate electrode on the substrate may further include forming a high-K dielectric layer between the carbon nanotube and the gate electrode surrounding the center portion of the carbon nanotube.

In one embodiment, after forming the porous silicon layer on the substrate and prior to introducing the metal catalyst onto the surface of the porous silicon layer, the method may further include: performing photolithography to remove a portion of the porous silicon layer beneath the carbon nanotube, such that the carbon nanotube is supported at its end portions by the remaining porous silicon layer.

In one embodiment, after introducing the metal catalyst onto the surface of the porous silicon layer and prior to reacting the metal catalyst with the carbon-based compound to form the carbon nanotube, the method may further include: removing the porous silicon layer such that the carbon nanotube is supported by the gate electrode.

In one embodiment, forming the porous silicon layer on the substrate may further include: depositing a heavily-doped polysilicon onto the substrate; and performing photolithography on the heavily-doped polysilicon to form the porous silicon layer.

In one embodiment, introducing the metal catalyst onto the surface of the porous silicon layer may further include: coating a photoresist on the porous silicon layer; removing a portion of the photoresist in a region where the carbon nanotube is to be formed, so as to expose the porous silicon layer in the region; injecting a solution containing the metal catalyst onto the exposed porous silicon layer in the region; baking the solution containing the metal catalyst in a nitrogen or hydrogen containing atmosphere to form metal nanoparticles; and removing the photoresist remaining on the porous silicon layer.

In one embodiment, after forming the gate electrode on the substrate and prior to forming the source electrode and the drain electrode on the substrate, the method may further include: forming a spacer on both side portions of the gate electrode.

In one embodiment, the metal catalyst may include at least one of platinum, gold, silver, copper, and nickel.

In one embodiment, the carbon nanotube may be a single-walled carbon nanotube.

### BRIEF DESCRIPTION OF THE DRAWINGS

The accompanying drawings, which are incorporated herein and constitute a part of the specification, illustrate different embodiments of the inventive concept and, together with the detailed description, serve to describe more clearly the inventive concept.

It is noted that in the accompanying drawings, for convenience of description, the dimensions of the components shown may not be drawn to scale. Also, same or similar reference numbers between different drawings represent the same or similar components.

FIG. 1 is a flowchart illustrating a method of manufacturing a field effect transistor according to an embodiment of the inventive concept.

FIG. 2 is a flowchart illustrating process step S1 of FIG. 1 in further detail.

FIG. 3 is a flowchart illustrating process step S11 of FIG. 2 in further detail.

FIG. 4 is a flowchart illustrating process step S12 of FIG. 2 in further detail.

FIG. 5 is a schematic perspective view illustrating a porous silicon layer formed on a substrate.

FIG. 6 is a schematic perspective view illustrating a photoresist structure formed on the porous silicon layer of FIG. 5.

FIG. 7 is a schematic perspective view illustrating metal nanoparticles formed in the porous silicon layer of FIG. 6.

FIG. 8 is a schematic perspective view illustrating a carbon nanotube formed on the porous silicon layer of FIG. 7.

FIG. 9 is a schematic perspective view illustrating a portion of the porous silicon layer of FIG. 8 being removed.

FIG. 10 is a schematic perspective view illustrating a gate electrode formed surrounding a center portion of the carbon nanotube.

FIG. 11 is a schematic perspective view illustrating the end portions of the porous silicon layer of FIG. 10 being removed.

FIG. 12 is a schematic perspective view illustrating a spacer formed on both side portions of the gate electrode of FIG. 11.

FIG. 13 is a schematic perspective view illustrating a source electrode and a drain electrode formed surrounding the respective ends of the carbon nanotube of FIG. 12.

### DETAILED DESCRIPTION

Various embodiments of the inventive concept are next described in detail with reference to the accompanying drawings. It is noted that the following description of the different embodiments is merely illustrative in nature, and is not intended to limit the inventive concept, its application, or use. The relative arrangement of the components and steps, and the numerical expressions and the numerical values set forth in these embodiments do not limit the scope of the inventive concept unless otherwise specifically stated. In addition, techniques, methods, and devices as known by those skilled in the art, although omitted in some instances, are intended to be part of the specification where appropriate. It should be noted that for convenience of description, the sizes of the elements in the drawings may not be drawn to scale.

In the drawings, the sizes and/or relative sizes of layers and regions may be exaggerated for clarity. Like reference numerals denote the same elements throughout.

It will be understood that, although the terms “first,” “second,” “third,” etc. may be used herein to describe various elements, the elements should not be limited by those terms. Instead, those terms are merely used to distinguish one element from another. Thus, a “first” element discussed below could be termed a “second “element without departing from the teachings of the present inventive concept. As used herein, the term “and/or” includes any and all combinations of one or more of the associated listed items.

It should be understood that the inventive concept is not limited to the embodiments described herein. Rather, the inventive concept may be modified in different ways to realize different embodiments.

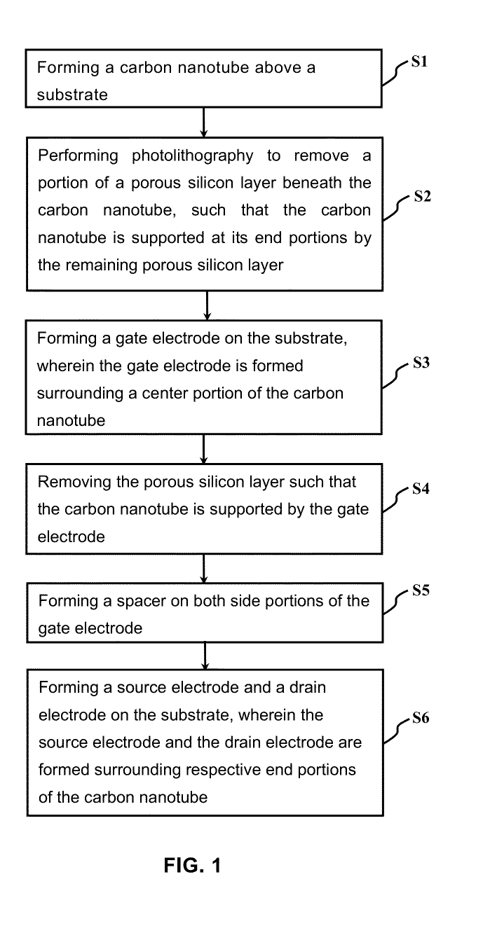

FIG. 1 is a flowchart illustrating a method of manufacturing a field effect transistor according to an embodiment of the inventive concept.

First, a carbon nanotube is formed over a substrate (step S1). For example, as shown in FIG. 8, a carbon nanotube 1004 may be formed above a silicon oxide layer 702 and a silicon substrate 701.

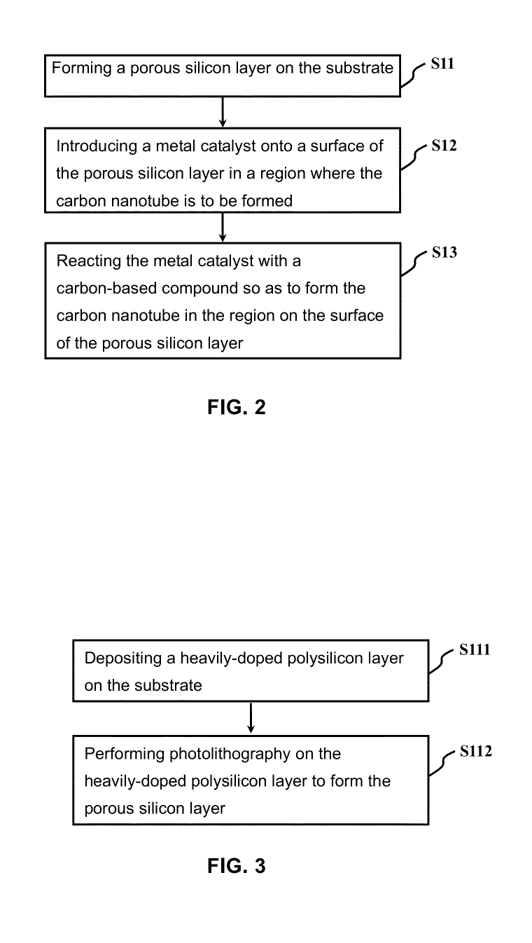

FIG. 2 is a flowchart illustrating process step S1 of FIG. 1 in further detail. Referring to FIG. 2, a porous silicon layer is formed on the substrate (step S11).

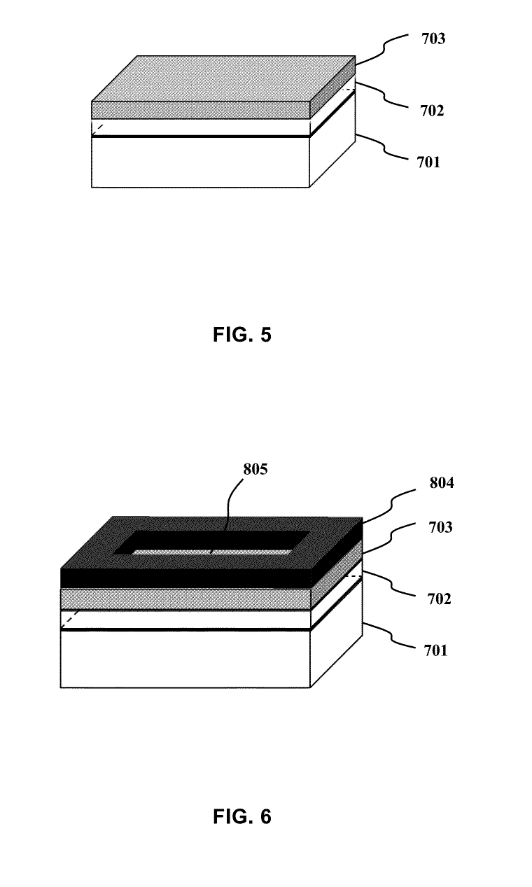

For example, as shown in FIG. 5, a porous silicon layer 703 may be formed on the silicon oxide layer 702 and the silicon substrate 701.

FIG. 3 is a flowchart illustrating process step S11 of FIG. 2 in further detail.

First, a heavily-doped polysilicon layer is deposited on the substrate (step S111). For example, as shown in FIG. 5, the silicon substrate 701 is provided, and the silicon oxide layer 702 is formed on the silicon substrate 701. A thickness of the silicon oxide layer 702 may range from about 10 nm to about 100 nm. In a preferred embodiment, the thickness of the silicon oxide layer 702 may be about 50 nm. Next, a heavily-doped polysilicon layer is deposited on the silicon oxide layer 702.

Referring back to FIG. 3, after step S111 is completed, photolithography is subsequently performed on the heavily-doped polysilicon layer to form the porous silicon layer (step S112). For example, referring to FIG. 5, photolithography is performed on the heavily-doped polysilicon layer (not shown) so as to form the porous silicon layer 703 on the silicon oxide layer 702. A thickness of the porous silicon layer 703 may range from about 2 nm to about 10 nm. In a preferred embodiment, the thickness of the porous silicon layer 703 may be about 5 nm.

Accordingly, a porous silicon layer (e.g. porous silicon layer 703) may be formed on a substrate using the steps illustrated in FIG. 3.

Referring back to FIG. 2, after step S11 is completed, a metal catalyst is introduced onto the surface of the porous silicon layer (in a region where the carbon nanotube is to be formed) (step S12). For example, as shown in FIG. 6, the metal catalyst may be introduced onto the surface of the porous silicon layer 703, specifically in a region 805 where the carbon nanotube is to be formed. The metal catalyst may, for example, include at least one of platinum, gold, silver, copper, and nickel.

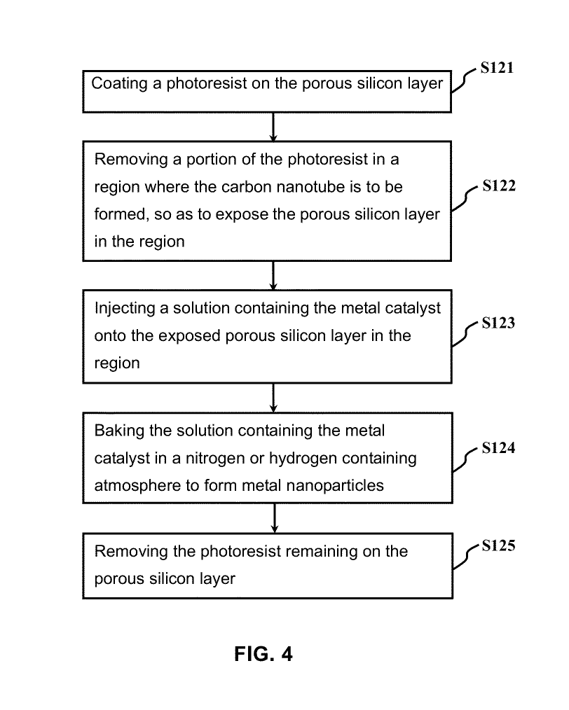

FIG. 4 is a flowchart illustrating process step S12 of FIG. 2 in further detail. First, a photoresist is coated on the porous silicon layer (step S121). For example, as shown in FIG. 6, a photoresist 804 may be coated on the porous silicon layer 703.

Next, a portion of the photoresist is removed in a region where the carbon nanotube is to be formed, so as to expose the porous silicon layer in the region (step S122).

For example, as shown in FIG. 6, the region 805 corresponds to a region where the carbon nanotube is to be formed. Accordingly, the portion of the photoresist in the region 805 may be removed so as to expose the porous silicon layer 703 in the region 805. Although the region 805 is formed having a rectangular shape, those skilled in the art would recognize that the region 805 is not limited to a rectangular shape, but may also be formed in other shapes (for example, an oval shape). In some embodiments, more than one region 805 may be formed (for example, a plurality of regions 805 may be formed). In some embodiments, the region 805 need not be centrally located with respect to the porous silicon layer 703, and can be disposed in locations that are away from the center of the porous silicon layer 703.

After step S122 is completed, a solution containing the metal catalyst is injected onto the exposed area of the porous silicon layer (step S123). For example, referring to FIG. 6, the solution containing the metal catalyst may be injected onto the exposed porous silicon layer 703 in the region 805. The metal catalyst may, for example, include at least one of platinum, gold, silver, copper, and nickel.

After step S123 is completed, the solution containing the metal catalyst is baked in a nitrogen or hydrogen containing atmosphere to form metal nanoparticles (step S124). For example, referring to FIG. 6, after the solution containing the metal catalyst is injected onto the exposed porous silicon layer 703 in the region 805, the solution is then baked in a nitrogen or hydrogen containing atmosphere to evaporate the solution, in the process forming the metal nanoparticles. The diameter of the metal nanoparticles may be, for example, about 3 nm or less. The metal nanoparticles serve as a metal catalyst for forming the carbon nanotube, as described in more detail later in the specification.

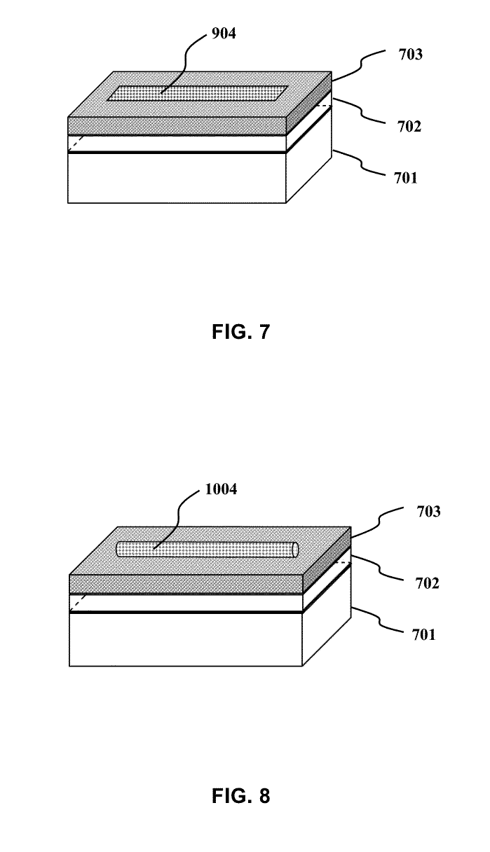

After step S124 is completed, the remaining photoresist on the porous silicon layer is removed (step S125). For example, the photoresist on the porous silicon layer 703 outside of the region 805 shown in FIG. 6 may be removed to produce the structure illustrated in FIG. 7. As shown in FIG. 7, the structure comprises a metal nano-particles layer 904 formed on a central region of the porous silicon layer 703, whereby all of the photoresist 804 is removed from the porous silicon layer 703.

Accordingly, a metal catalyst can be introduced onto the surface of the porous silicon layer (in a region where the carbon nanotube is to be formed) using the steps illustrated in FIG. 4.

Referring back to FIG. 2, after step S12 is completed, the metal catalyst undergoes a reaction with a carbon-based compound (e.g. carbonyl compound) to form a carbon nanotube on the surface of the porous silicon layer (step S13). For example, referring to FIG. 8, the carbon nanotube 1004 can be formed on the surface of the porous silicon layer 703 by reacting the metal catalyst with the carbon-based compound. Various techniques can be used to create the reaction between the metal catalyst and the carbon-based compound to form the carbon nanotube 1004. In one embodiment, when forming the carbon nanotube 1004 using a chemical vapor deposition (CVD) technique, the metal catalyst is introduced into the CVD environment at an ambient temperature (e.g., at a temperature below 100 degrees Celsius) and reacts with the carbon-based compound to form the carbon nanotube 1004. In another embodiment, when forming the carbon nanotube 1004 using a graphite arc discharge technique, a current is passed between two graphite electrodes to produce a spark (electrical discharge), thereby causing the metal catalyst to react with the carbon-based compound to form the carbon nanotube 1004. Those skilled in the art would understand that the above-described CVD and arc discharge techniques are merely exemplary, and that other methods can be used to create the reaction between the metal catalyst and the carbon-based compound to form the carbon nanotube 1004.

The carbon-based compound may include, for example, at least one of methane, ethylene, acetylene, carbon monoxide, and benzene. Those skilled in the art would recognize that other types of carbon-based compounds may be used, as long as those other types of carbon-based compounds can react with the metal catalyst to form carbon nanotubes.

Carbon nanotubes are generally formed by rolling together layers of graphene sheets. Depending on the number of graphene sheet layers, the carbon nanotubes may be categorized into single-walled carbon nanotubes (SWCNT) or multi-walled carbon nanotubes (MWCNT).

When forming MWCNTs, defects can be easily formed in the gap between the graphene sheet layers. As a result, the walls of the MWCNTs often have numerous small hole-like defects. In contrast, the range of diameters of the nanotubes for SWCNTs is generally smaller than that of MWCNTs. As a result, SWCNTs typically have fewer defects and are more uniform compared to MWCNTs. The diameter of a SWCNT generally ranges from about 0.6 nm to about 2 nm. On the other hand, the diameter of a MWCNT may range from about 0.4 nm (in the innermost layer) to hundreds of nanometers at its thickest portion. However, the diameter of a MWCNT generally ranges from about 2 nm to about 100 nm.

In a preferred embodiment of the inventive concept, the carbon nanotube may be a single-walled carbon nanotube.

Accordingly, a carbon nanotube can be formed above the substrate using the steps illustrated in FIG. 2

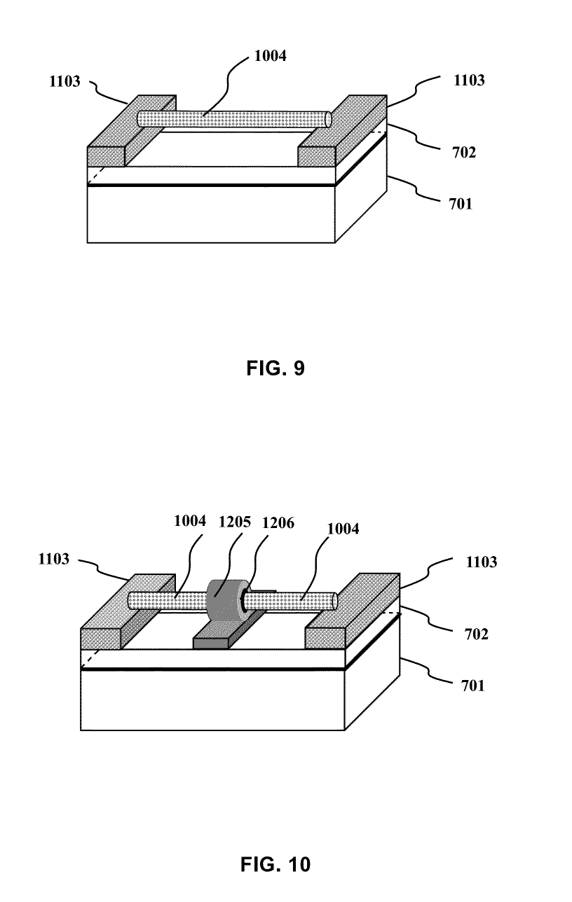

Referring back to FIG. 1, after step S1 is completed, photolithography is performed to remove the portion of the porous silicon layer beneath the carbon nanotube, such that the carbon nanotube is supported at its end portions by the remaining porous silicon layer (step S2). For example, referring to FIG. 9, photolithography is performed on the porous silicon layer 703, so as to remove the portion of the porous silicon layer 703 beneath the carbon nanotube 1004. However, the portion of the porous silicon layer 703 at the two ends of the carbon nanotube 1004 is not removed by the photolithography, as depicted by the remaining porous silicon layer 1103. As shown in FIG. 9, the two ends of the carbon nanotube 1004 are supported by the remaining porous silicon layer 1103. Those skilled in the art would recognize that different portions of the porous silicon layer 703 may be removed in different configurations depending on device and structural needs, so long as the remaining porous silicon layer 1103 is capable of supporting the carbon nanotube 1004 at its two ends.

After step S2 is completed, a gate electrode is formed on the substrate, whereby the gate electrode is formed surrounding a center portion of the carbon nanotube (step S3).

In a preferred embodiment, a high-K dielectric layer may be formed between the carbon nanotube and the gate electrode surrounding the center portion of the carbon nanotube. For example, referring to FIG. 10, a high-K dielectric layer 1206 may be formed between the carbon nanotube 1004 and the gate electrode 1205 surrounding the center portion of the carbon nanotube 1004. Specifically, a high-K dielectric layer may be formed completely surrounding the carbon nanotube, and photolithography may be performed to remove the portions of the high-K dielectric layer that are outside of the center portion of the carbon nanotube. Accordingly, the high-K dielectric layer 1206 is left remaining on (and surrounding) the center portion of the carbon nanotube 1004.

Next, the gate electrode 1205 is formed surrounding the high-K dielectric layer 1206. Specifically, the gate electrode 1205 is formed surrounding the center portion of the carbon nanotube 1004. By forming the gate electrode such that it is wrapped around the center portion of the carbon nanotube, the control of the gate electrode over the channel of the carbon nanotube can be improved, thereby reducing the electron barrier between the source electrode and the drain electrode.

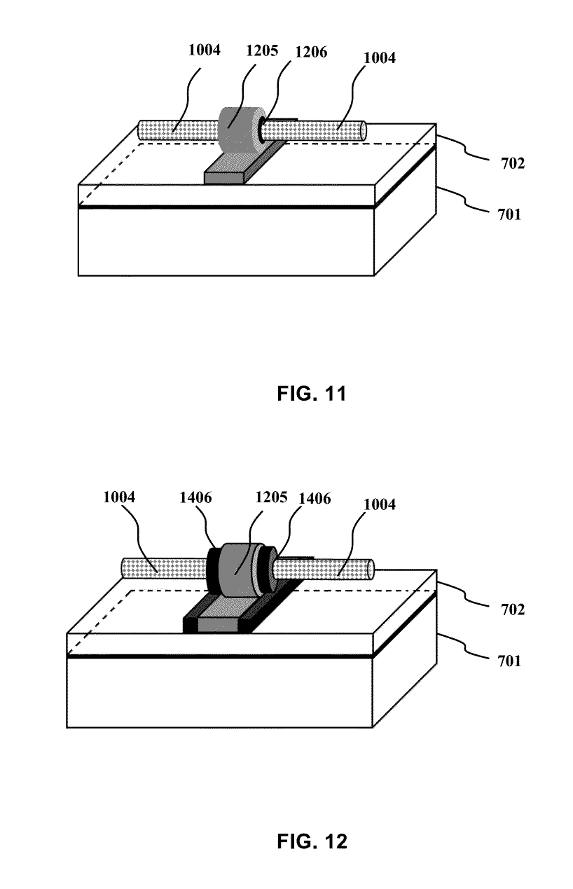

After step S3 is completed, the remaining porous silicon layer is removed such that the carbon nanotube is supported by the gate electrode (step S4). For example, referring to FIG. 11, after the remaining porous silicon layer 1103 at the two ends of the carbon nanotube 1004 is removed, the carbon nanotube 1004 will be supported by the gate electrode 1205 at its center portion.

After step S4 is completed, a spacer is formed on both side portions of the gate electrode (step S5). For example, referring to FIG. 12, a spacer 1406 may be formed on both side portions of the gate electrode 1205. The spacer 1406 may be formed of an insulating material, such as silicon oxide, silicon nitride, and the like.

Those skilled in the art would appreciate that the above sequence of steps S4 and S5 can be reversed. For example, in some alternative embodiments, step S5 may be carried out before step S4.

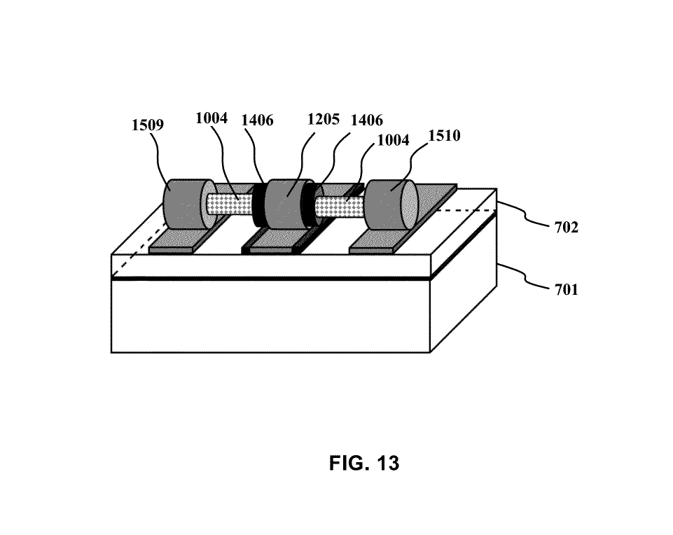

After step S5 is completed, a source electrode and a drain electrode are formed on the substrate, whereby the source electrode and the drain electrode are formed surrounding respective end portions of the carbon nanotube (step S6). For example, referring to FIG. 13, a source/drain electrode 1509 may be formed on the substrate, with the source/drain electrode 1509 surrounding the left end portion of the carbon nanotube 1004. Similarly, a source/drain electrode 1510 may be formed on the substrate, with the source/drain electrode 1510 surrounding the right end portion of the carbon nanotube 1004.

By forming the source and drain electrodes such that they are wrapped around the respective end portions of the carbon nanotube, the contact resistance of the source and drain electrodes of the carbon nanotube can be improved.

Embodiments of a field effect transistor and methods of manufacturing the field effect transistor have been described in the foregoing description. To avoid obscuring the inventive concept, details that are well-known in the art may have been omitted. Nevertheless, those skilled in the art would be able to understand the implementation of the inventive concept and its technical details in view of the present disclosure.

The different embodiments of the inventive concept have been described with reference to the accompanying drawings. However, the different embodiments are merely illustrative and are not intended to limit the scope of the inventive concept. Furthermore, those skilled in the art would appreciate that various modifications can be made to the different embodiments without departing from the scope of the inventive concept.

What is claimed is:

1. A field effect transistor comprising:
a substrate;
a carbon nanotube formed above the substrate;
a gate electrode formed on the substrate, wherein the gate electrode is formed surrounding a center portion of the carbon nanotube; and
a source electrode and a drain electrode formed on the substrate, wherein the source electrode and the drain electrode are formed surrounding respective end portions of the carbon nanotube.

2. The field effect transistor according to claim 1, further comprising:
a high-K dielectric layer formed between the carbon nanotube and the gate electrode surrounding the center portion of the carbon nanotube.

3. The field effect transistor according to claim 1, further comprising:
a spacer formed on both side portions of the gate electrode.

4. The field effect transistor according to claim 1, wherein the carbon nanotube is formed by reacting a metal catalyst with a carbon-based compound.

5. The field effect transistor according to claim 4, wherein the carbon-based compound comprises at least one of methane, ethylene, acetylene, carbon monoxide, and benzene.

6. The field effect transistor according to claim 4, wherein the metal catalyst comprises at least one of platinum, gold, silver, copper, and nickel.

7. The field effect transistor according to claim 1, wherein the carbon nanotube is a single-walled carbon nanotube.

8. A method of manufacturing a field effect transistor, comprising:
forming a carbon nanotube above a substrate;
forming a gate electrode on the substrate, wherein the gate electrode is formed surrounding a center portion of the carbon nanotube; and
forming a source electrode and a drain electrode on the substrate, wherein the source electrode and the drain electrode are formed surrounding respective end portions of the carbon nanotube.

9. The method according to claim 8, wherein forming the carbon nanotube above the substrate further comprises:
forming a porous silicon layer on the substrate;
introducing a metal catalyst onto a surface of the porous silicon layer in a region where the carbon nanotube is to be formed; and
reacting the metal catalyst with a carbon-based compound so as to form the carbon nanotube in the region on the surface of the porous silicon layer.

10. The method according to claim 9, wherein the carbon-based compound comprises at least one of methane, ethylene, acetylene, carbon monoxide, and benzene.

11. The method according to claim 8, wherein forming the gate electrode on the substrate further comprises:
forming a high-K dielectric layer between the carbon nanotube and the gate electrode surrounding the center portion of the carbon nanotube.

12. The method according to claim 9, wherein after forming the porous silicon layer on the substrate and prior to introducing the metal catalyst onto the surface of the porous silicon layer, the method further comprises:
performing photolithography to remove a portion of the porous silicon layer beneath the carbon nanotube, such that the carbon nanotube is supported at its end portions by the remaining porous silicon layer.

13. The method according to claim 9, wherein after introducing the metal catalyst onto the surface of the porous silicon layer and prior to reacting the metal catalyst with the carbon-based compound to form the carbon nanotube, the method further comprises:
removing the porous silicon layer such that the carbon nanotube is supported by the gate electrode.

14. The method according to claim 9, wherein forming the porous silicon layer on the substrate further comprises:
depositing a heavily-doped polysilicon onto the substrate; and
performing photolithography on the heavily-doped polysilicon to form the porous silicon layer.

15. The method according to claim 9, wherein introducing the metal catalyst onto the surface of the porous silicon layer further comprises:
coating a photoresist on the porous silicon layer;
removing a portion of the photoresist in a region where the carbon nanotube is to be formed, so as to expose the porous silicon layer in the region;
injecting a solution containing the metal catalyst onto the exposed porous silicon layer in the region;
baking the solution containing the metal catalyst in a nitrogen or hydrogen containing atmosphere to form metal nanoparticles; and
removing the photoresist remaining on the porous silicon layer.

16. The method according to claim 8, wherein after forming the gate electrode on the substrate and prior to forming the source electrode and the drain electrode on the substrate, the method further comprises:
forming a spacer on both side portions of the gate electrode.

17. The method according to claim 9, wherein the metal catalyst comprises at least one of platinum, gold, silver, copper, and nickel.

18. The method according to claim 8, wherein the carbon nanotube is a single-walled carbon nanotube.
